(19) United States
(12) Patent Application Publication
(10) Pub. No.: US 2012/0273758 A1
(43) Pub. Date: Nov. 1, 2012

(54) NITRIDE SEMICONDUCTOR LIGHT-EMITTING DIODE DEVICE

(75) Inventor: Satoshi KOMADA, Osaka-shi (JP)

(73) Assignee: Sharp Kabushiki Kaisha, Osaka-shi (JP)

(21) Appl. No.: 13/432,513

(22) Filed: Mar. 28, 2012

(30) Foreign Application Priority Data
Apr. 28, 2011 (JP) 2011-100952

(51) Int. Cl. H01L 33/06

(52) U.S. Cl. 257/13; 257/E33.008

(57) ABSTRACT

A nitride semiconductor light-emitting diode device includes an n-type nitride semiconductor layer, a p-type nitride semiconductor layer and an active layer provided between the n-type nitride semiconductor layer and the p-type nitride semiconductor layer, while the active layer has a multiple quantum well structure including a quantum well layer and a barrier layer in contact with the p-type semiconductor layer, the barrier layer consists of a two-layer structure of an AlGaN layer and a GaN layer, and the AlGaN layer included in the barrier layer is in contact with a side of the quantum well layer closer to the p-type nitride semiconductor layer

This nonprovisional application is based on Japanese Patent Application No. 2011-100952 filed on Apr. 28, 2011 with the Japan Patent Office, the entire contents of which are hereby incorporated by reference.

### BACKGROUND OF THE INVENTION

1. Field of the Invention

The present invention relates to a nitride semiconductor light-emitting diode device.

2. Description of the Background Art

In general, a multiple quantum well structure obtained by alternately stacking quantum well layers and barrier layers is employed for an active layer of a nitride semiconductor light-emitting device such as a nitride semiconductor light-emitting diode device, in order to ensure high luminous efficiency for the nitride semiconductor light-emitting device.

For example, Patent Document 1 (Japanese Patent Laying-Open No. 2007-201146) discloses a nitride semiconductor light-emitting device employing AlGaN layers as barrier layers of an active layer having a multiple quantum well structure.

According to Patent Document 1, strains of quantum well layers included in the active layer can be relaxed by employing the barrier layers made of AlGaN and electrons and holes can be efficiently supplied to the active layer by reducing the thickness of the barrier layers made of AlGaN, whereby luminous efficiency of the nitride semiconductor light-emitting device is improved.

### SUMMARY OF THE INVENTION

It is a common problem for a nitride semiconductor light-emitting diode device that a droop phenomenon takes place to reduce luminous efficiency of the nitride-semiconductor light-emitting diode device when high-density current is injected into an active layer.

The droop phenomenon is caused by an overflow of electrons into a p-type nitride semiconductor layer resulting from difference in diffusion length between the electrons and holes. Further, the droop phenomenon is enhanced by carriers not uniformly distributed in the thickness direction of an active layer having a multiple quantum well structure but localized on a portion of the active layer closer to the p-type nitride semiconductor layer to increase the carrier concentration in this portion.

In recent years, however, a demand for a nitride semiconductor light-emitting diode device driven with high current density to be applied to LED illumination or the like has been increased, and hence a nitride semiconductor light-emitting diode device capable of suppressing reduction of luminous efficiency resulting from a droop phenomenon also when driven with high current density is increasingly required.

In consideration of the aforementioned circumstances, an object of the present invention is to provide a nitride semiconductor light-emitting diode device capable of suppressing reduction of luminous efficiency when high-density current is injected into an active layer.

According to a first aspect of the present invention, a nitride semiconductor light-emitting diode device including an n-type nitride semiconductor layer, a p-type nitride semiconductor layer and an active layer provided between the n-type nitride semiconductor layer and the p-type nitride semiconductor layer, in which the active layer has a multiple quantum well structure including a quantum well layer and a barrier layer in contact with the p-type semiconductor layer, the barrier layer consists of a two-layer structure of an AlGaN layer and a GaN layer, the AlGaN layer included in the barrier layer is in contact with a side of the quantum well layer closer to the p-type nitride semiconductor layer and the content of Al atoms in the AlGaN layer is at least 10 atomic %, can be provided.

In the nitride semiconductor light-emitting diode device according to the first aspect of the present invention, the thickness of the AlGaN layer is preferably at least 1 nm and not more than 4 nm.

According to a second aspect of the present invention, a nitride semiconductor light-emitting diode device including an n-type nitride semiconductor layer, a p-type nitride semiconductor layer and an active layer provided between the n-type nitride semiconductor layer and the p-type nitride semiconductor layer, in which the active layer has a multiple quantum well structure including a quantum well layer, a first barrier layer including an InGaN layer in contact with a side of the quantum well layer closer to the n-type nitride semiconductor layer and a second barrier layer including an AlGaN layer in contact with a side of the quantum well layer closer to the p-type nitride semiconductor layer, can be provided.

In the nitride semiconductor light-emitting diode device according to the second aspect of the present invention, the thickness of the InGaN layer included in the first barrier layer is preferably at least 1 nm and not more than 4 nm.

In the nitride semiconductor light-emitting diode device according to the second aspect of the present invention, the quantum well layer preferably contains In, and the content of In atoms in the InGaN layer included in the first barrier layer is preferably smaller than the content of In atoms in the quantum well layer.

In the nitride semiconductor light-emitting diode device according to the second aspect of the present invention, the content of the In atoms in the InGaN layer included in the first barrier layer is preferably at least 0.3 times and not more than 0.7 times the content of the In atoms in the quantum well layer.

In the nitride semiconductor light-emitting diode device according to the second aspect of the present invention, the thickness of the AlGaN layer included in the second barrier layer is preferably at least 1 nm and not more than 4 nm.

According to a third aspect of the present invention, a nitride semiconductor light-emitting diode device including an n-type nitride semiconductor layer, a p-type nitride semiconductor layer and an active layer provided between the n-type nitride semiconductor layer and the p-type nitride semiconductor layer, in which the active layer has a multiple quantum well structure including a quantum well layer and a barrier layer in contact with the p-type semiconductor layer, the barrier layer consists of a two-layer structure of an AlGaN layer and a GaN layer, the AlGaN layer included in the barrier layer is in contact with a side of the quantum well layer closer to the p-type nitride semiconductor layer, and the AlGaN layer contains at least either Mg or In, can be provided.

In the nitride semiconductor light-emitting diode device according to the third aspect of the present invention, the Mg concentration in the AlGaN layer is preferably at least 1×10¹⁸/cm³ and not more than 1×10²⁰/cm³.

In the nitride semiconductor light-emitting diode device according to the third aspect of the present invention, the content of In atoms in the AlGaN layer is preferably at least 0.01 atomic % and not more than 5 atomic %.

In the nitride semiconductor light-emitting diode device according to the third aspect of the present invention, the thickness of the AlGaN layer is preferably at least 1 nm and not more than 4 nm.

According to a fourth aspect of the present invention, a nitride semiconductor light-emitting diode device including an n-type nitride semiconductor layer, a p-type nitride semiconductor layer and an active layer provided between the n-type nitride semiconductor layer and the p-type nitride semiconductor layer, in which the active layer has a multiple quantum well structure including a quantum well layer, a first barrier layer consisting of a single GaN layer and a second barrier layer consisting of a two-layer structure of an AlGaN layer and a GaN layer, the quantum well layer includes a first quantum well layer arranged on a position of the quantum well layer closest to the n-type nitride semiconductor layer and a second quantum well layer arranged on a position of the quantum well layer closest to the p-type nitride semiconductor layer, and the first barrier layer is arranged on a side of the first quantum well layer closer to the p-type nitride semiconductor layer and a side of the second quantum well layer closer to the p-type nitride semiconductor layer respectively, and the quantum well layer other than the first quantum well layer and the second quantum well layer is formed in contact with the second barrier layer, can be provided.

In the nitride semiconductor light-emitting diode device according to each of the first to fourth aspects of the present invention, the number of quantum well periods in the multiple quantum well structure is preferably at least 6 and not more than 20.

In the nitride semiconductor light-emitting diode device according to each of the first to fourth aspects of the present invention, further, the n-type nitride semiconductor layer, the p-type nitride semiconductor layer and the active layer preferably have major surfaces of c-planes respectively.

According to the present invention, a nitride semiconductor light-emitting diode device capable of suppressing reduction of luminous efficiency when high-density current is injected into an active layer can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a nitride semiconductor light-emitting diode device according to a first embodiment of the present invention;

FIGS. 2 to 5 are sectional views illustrating exemplary steps of manufacturing the nitride semiconductor light-emitting diode device according to the first embodiment;

FIG. 6 is a schematic sectional view of a nitride semiconductor light-emitting diode device according to a second embodiment of the present invention;

FIG. 7 is a schematic sectional view of a nitride semiconductor light-emitting diode device according to a third embodiment of the present invention;

FIG. 8 is a schematic sectional view of a nitride semiconductor light-emitting diode device according to a fourth embodiment of the present invention;

FIGS. 9 to 15 are sectional views illustrating exemplary steps of manufacturing a nitride semiconductor light-emitting diode device according to Example 1; and

FIG. 16 is a schematic sectional view of the nitride semiconductor light-emitting diode device according to Example 1.

### DESCRIPTION OF THE PREFERRED EMBODIMENTS

Embodiments of the present invention are now described with reference to the accompanying drawings. Referring to the drawings, it is assumed that the same reference signs denote identical or corresponding portions.

### First Embodiment

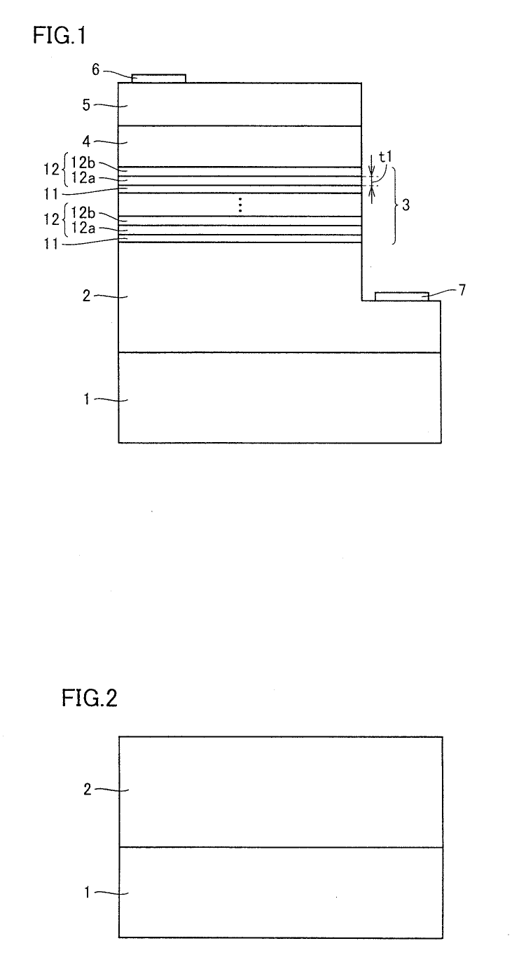

FIG. 1 is a schematic sectional view of a nitride semiconductor light-emitting diode device according to a first embodiment of the present invention. The nitride semiconductor light-emitting diode device according to the present invention includes a substrate 1, an n-type nitride semiconductor layer 2 provided on substrate 1, an active layer 3 provided on n-type nitride semiconductor layer 2, a p-type nitride semiconductor layer 4 provided on active layer 3, a transparent conductive layer 5 provided on p-type nitride semiconductor layer 4, a p-side electrode 6 provided on transparent conductive layer 5 and an n-side electrode 7 provided on n-type nitride semiconductor layer 2.

Active layer 3 is provided between n-type nitride semiconductor layer 2 and p-type nitride semiconductor layer 4, and has a structure obtained by alternately stacking quantum well layers 11 and barrier layers 12 from a side closer to n-type nitride semiconductor layer 2. In other words, active layer 3 has a multiple quantum well structure including plurality of quantum well layers 11.

Barrier layers 12 have two-layer structures of AlGaN layers 12a and GaN layers 12b provided on AlGaN layers 12a, and GaN layer 12b constituting uppermost barrier layer 12 of active layer 3 is in contact with p-type nitride semiconductor layer 4. On the other hand, lowermost quantum well layer 11 of active layer 3 is in contact with n-type nitride semiconductor layer 12, and AlGaN layer 12a of lowermost barrier layer 12 is in contact with a surface of lowermost quantum well layer 11 closer to p-type nitride semiconductor layer 4. In other words, active layer 3 has a structure obtained by repeatedly stacking quantum well layers 11, AlGaN layers 12a and GaN layers 12b in this order from the side closer to n-type nitride semiconductor layer 2 to a side closer to p-type nitride semiconductor layer 4.

An exemplary method of manufacturing the nitride semiconductor light-emitting diode device according to the first embodiment is now described with reference to schematic sectional views shown in FIGS. 2 to 5. First, n-type nitride semiconductor layer 2 is stacked on substrate 1, as shown in FIG. 2. N-type nitride semiconductor layer 2 can be formed on substrate 1 by MOCVD (Metal Organic Chemical Vapor Deposition) or the like, for example.

A sapphire (Al₂O₃) substrate, a GaN self-supporting substrate, an SiC substrate, a spinel (MgAl₂O₄) substrate or a ZnO substrate, for example, can be employed as substrate 1.

A nitride semiconductor crystal prepared by doping a nitride semiconductor expressed as Alₓ₁Ga_{y1}In_{z1}N (0≦x1≦1, 0≦y1≦1, 0≦z1≦1 and x1+y1+z1≠0) with an n-type dopant such as Si or the like, for example, can be employed as the material for n-type nitride semiconductor layer 2. N-type nitride semiconductor layer 2 is not restricted to a single layer, but may be formed by a plurality of layers including a low-temperature buffer layer, an undoped layer and a superlattice layer having different compositions and/or containing the n-type dopant in different doping concentrations. When partially including an undoped layer, n-type nitride semiconductor layer 2 may exhibit an n conductivity type as a whole.

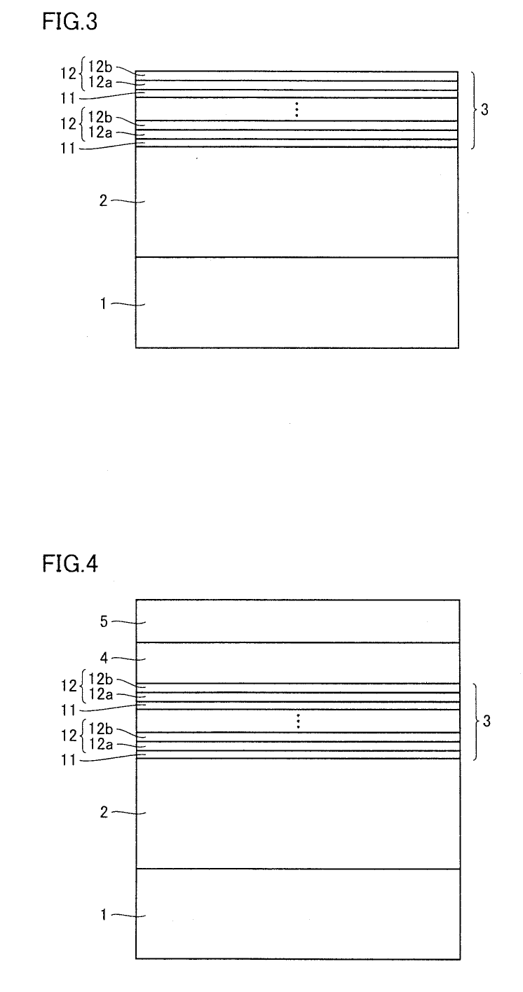

Then, active layer 3 is stacked on n-type nitride semiconductor layer 2, as shown in FIG. 3. Active layer 3 can be formed by repeatedly stacking quantum well layers 11, AlGaN layers 12a and GaN layers 12b in this order on n-type nitride semiconductor layer 2 by MOCVD or the like, for example.

A nitride semiconductor crystal expressed as Alₓ₂Ga_{y2}In_{z2}N (0≦x2≦1, 0≦y2≦1, 0≦z2≦1 and x2+y2+z2≠0) or the like, for example, can be employed as the material for quantum well layers 11, and a nitride semiconductor crystal expressed as Ga_{y2}In_{z2}N (0<y2<1, 0<z2<1 and y2+z2<1) is particularly preferably employed as the material for quantum well layers 11.

A nitride semiconductor crystal expressed as Alₓ₃Ga_{y3}N (0.1≦x3<1, 0<y3<1 and x3+y3≠0) is employed as the material for AlGaN layers 12a. In other words, the content of Al atoms in AlGaN layers 12a is set to at least 10 atomic %.

The band gaps of AlGaN layers 12a and GaN layers 12b are larger than that of the quantum well layers 11 respectively, while the band gap of AlGaN layers 12a is larger than that of GaN layers 12b.

Then, p-type nitride semiconductor layer 4 is stacked on active layer 3 and transparent conductive layer 5 is stacked on p-type nitride semiconductor layer 4, as shown in FIG. 4. P-type nitride semiconductor layer 4 can be formed on active layer 3 by MOCVD or the like, for example. Transparent conductive layer 5 can be formed on p-type nitride semiconductor layer 4 by sputtering or the like, for example.

A nitride semiconductor crystal prepared by doping a nitride semiconductor expressed as Alₓ₅Ga_{y5}In_{z5}N (0≦x5≦1, 0≦y5≦1, 0≦z5≦1 and x5+y5+z5≠0) with a p-type dopant such as Mg or the like, for example, can be employed as the material for p-type nitride semiconductor layer 4.

A transparent conductive film of ITO (Indium Tin Oxide) or the like, for example, can be employed as transparent conductive layer 5.

Then, the surface of n-type nitride semiconductor layer 2 is exposed by partially photoetching n-type nitride semiconductor layer 2, active layer 3, p-type nitride semiconductor layer 4 and transparent conductive layer 5, as shown in FIG. 5.

Then, p-side electrode 6 is formed on the surface of transparent conductive layer 5 while n-side electrode 7 is formed on the exposed surface of n-type nitride semiconductor layer 2, as shown in FIG. 1. P-side electrode 6 can be formed by stacking a Ti layer, an Al layer and an Au layer in this order on the surface of transparent conductive layer 5, for example. N-side electrode 7 can be formed by stacking a Ti layer, an Al layer and an Au layer in this order on the exposed surface of n-type nitride semiconductor layer 2, for example.

Thus, the nitride semiconductor light-emitting diode device according to the first embodiment is manufactured as shown in FIG. 1.

In the nitride semiconductor light-emitting diode device according to the first embodiment, the content of Al atoms in AlGaN layers 12a of barrier layers 12 of active layer 3 in contact with surfaces of quantum well layers 11 closer to p-type nitride semiconductor layer 4 is set to at least 10 atomic %. Thus, electrons injected into active layer 3 can be inhibited from overflowing into p-type nitride semiconductor layer 4 by increasing energy difference between conduction bands of quantum well layers 11 and AlGaN layers 12a. On the other hand, holes injected into active layer 3 can move toward n-type nitride semiconductor layer 2 from the valence bands of quantum well layers 11 up to those of AlGaN layers 12a through the valence bands of GaN layers 12b which are intermediate energy bands therebetween. Therefore, the holes can more easily move in active layer 3 as compared with the electrons, and a diffusion length of the holes with respect to the electrons in active layer 3 can be increased. According to the first embodiment, therefore, the difference in diffusion length between the electrons and the holes in active layer 3 can be reduced as compared with a case where no AlGaN layers 12a are provided, whereby not only the electrons can be inhibited from overflowing into p-type nitride semiconductor layer 4, but also localization of carriers on a side of active layer 3 closer to p-type nitride semiconductor layer 4 can be suppressed by uniformly distributing the carriers in the thickness direction of active layer 3 having the multiple quantum well structure.

The nitride semiconductor light-emitting diode device according to the first embodiment can be inhibited from reduction of luminous efficiency resulting from a droop phenomenon also when the same is driven with high current density, due to the aforementioned reasons. Therefore, the nitride semiconductor light-emitting diode device can be inhibited from reduction of luminous efficiency when high-density current is injected into active layer 3.

In the nitride semiconductor light-emitting diode device according to the first embodiment shown in FIG. 1, the thickness t1 of each AlGaN layer 12a is preferably at least 1 nm and not more than 4 nm. When the thickness t1 of each AlGaN layer 12a is at least 1 nm and not more than 4 nm, holes easily tunnel through AlGaN layers 12a to easily diffuse into active layer 3, whereby uniformity in distribution of the carriers into active layer 3 can be improved, and reduction of luminous efficiency resulting from a droop phenomenon tends to be further suppressible.

The number of quantum well periods in the multiple quantum well structure of active layer 3 is preferably at least 6 and not more than 20. If the number of quantum well periods in the multiple quantum well structure of active layer 3 is at least 6, such a tendency increases that the carriers can be uniformly distributed in the thickness direction of active layer 3. If the number of quantum well periods in the multiple quantum well structure of active layer 3 is not more than 20, the thickness of active layer 3 tends not to excessively increase as compared with the diffusion length of the carriers. When the number of quantum well periods in the multiple quantum well structure of active layer 3 is at least 6 and not more than 20, therefore, reduction of luminous efficiency resulting from a droop phenomenon can be further suppressed. When n-type nitride semiconductor layer 2, active layer 3 and p-type nitride semiconductor layer 4 have major surfaces (growth surfaces) of c-planes respectively, a piezoelectric field formed in the nitride semiconductor light-emitting diode device disturbs transportation of the holes. However, the nitride semiconductor light-emitting diode device according to the first embodiment can usefully exhibit high luminous efficiency also when such a piezoelectric field is formed.

### Second Embodiment

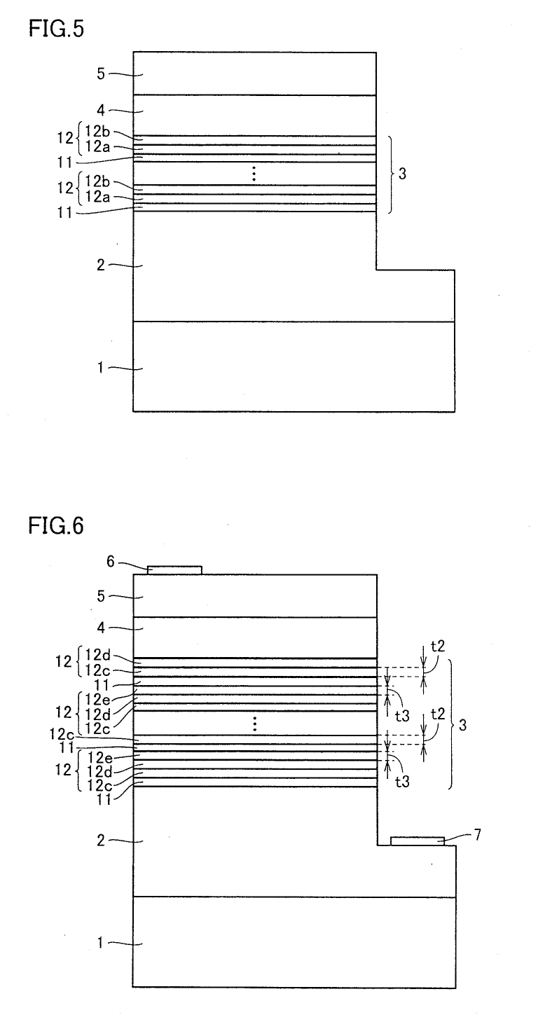

FIG. 6 is a schematic sectional view of a nitride semiconductor light-emitting diode device according to a second embodiment of the present invention. The feature of the nitride semiconductor light-emitting diode device according to the second embodiment resides in that the structure of an active layer 3 is different from that in the first embodiment.

In other words, quantum well layers 11, AlGaN layers 12c, GaN layers 12d and InGaN layers 12e are repeatedly stacked in this order from a side closer to an n-type nitride semiconductor layer 2 in active layer 3 of the nitride semiconductor light-emitting diode device according to the second embodiment, to form such a multiple quantum well structure that the stacking is completed on uppermost GaN layer 12d.

InGaN layers 12e are in contact with surfaces, closer to n-type nitride semiconductor layer 2, of quantum well layers 11 of active layer 3 other than lowermost quantum well layer 11, while AlGaN layers 12c are in contact with surfaces closer to a p-type nitride semiconductor layer 4.

In the nitride semiconductor light-emitting diode device according to the second embodiment, nitride semiconductor layers are so arranged (in order of InGaN layer 12e, GaN layer 12d and AlGaN layer 12c) that band gaps gradually enlarge from a side of quantum well layers 11 to a side of n-type nitride semiconductor layer 2 in a lowermost barrier layer 12 of active layer 3.

Therefore, holes diffusing from quantum well layers 11 into barrier layers 12 can move toward n-type nitride semiconductor layer 2 through valence bands of InGaN layers 12e and GaN layers 12d which are successively enlarging two-stage intermediate energy bands from valence bands of quantum well layers 11 to those of AlGaN layers 12c, whereby the holes can more easily move in active layer 3 as compared with electrons, and a diffusion length of the holes with respect to the electrons can be increased in active layer 3.

Also in the nitride semiconductor light-emitting diode device according to the second embodiment, therefore, not only the electrons can be inhibited from overflowing into p-type nitride semiconductor layer 4, but also localization of carriers on a side of active layer 3 closer to p-type nitride semiconductor layer 4 can be suppressed by uniformly distributing the carriers in the thickness direction of active layer 3 having the multiple quantum well structure, whereby reduction of luminous efficiency resulting from a droop phenomenon can be suppressed.

The thickness t2 of each AlGaN layer 12c in contact with corresponding quantum well layer 11 is preferably at least 1 nm and not more than 4 nm. In this case, the thickness t2 of each AlGaN layer 12c in contact with corresponding quantum well layer 11 can be sufficiently reduced, whereby quantum well layers 11 formed on barrier layers 12 in contact with quantum well layers 11 can be prevented from deterioration of crystallinity.

If quantum well layers 11 are formed by nitride semiconductor crystals containing In, the content of In atoms in InGaN layers 12e included in barrier layers 12 is preferably smaller than the content of In atoms in quantum well layers 11, and the content of In atoms in InGaN layers 12e included in barrier layers 12 is more preferably at least 0.3 times and not more than 0.7 times the content of In atoms in quantum well layers 11. In this case, an effect of suppressing reduction of luminous efficiency resulting from a droop phenomenon caused by the provision of the two-stage intermediate energy bands of InGaN layers 12e and GaN layers 12d tends to be further increasable.

The thickness t3 of each InGaN layer 12e in contact with corresponding quantum well layer 11 is preferably at least 1 nm and not more than 4 nm. In this case, the thickness t3 of each InGaN layer 12e in contact with corresponding quantum well layer 11 can be sufficiently reduced, whereby quantum well layers 11 formed on barrier layers 12 in contact with quantum well layers 11 can be prevented from deterioration of crystallinity.

A nitride semiconductor crystal expressed as Alₓ₆Ga_{y6}In_{z6}N (0≦x6≦1, 0≦y6≦1, 0≦z6≦1 and x6+y6+z6≠0) or the like, for example, can be employed as the material for AlGaN layers 12c.

A nitride semiconductor crystal expressed as Ga_{y8}In_{z8}N (0<y8<1, 0<z8<1 and y8+z8<1) or the like, for example, can be employed as the material for InGaN layers 12e.

The remaining structure of the second embodiment is similar to that of the first embodiment, and hence redundant description is not repeated.

### Third Embodiment

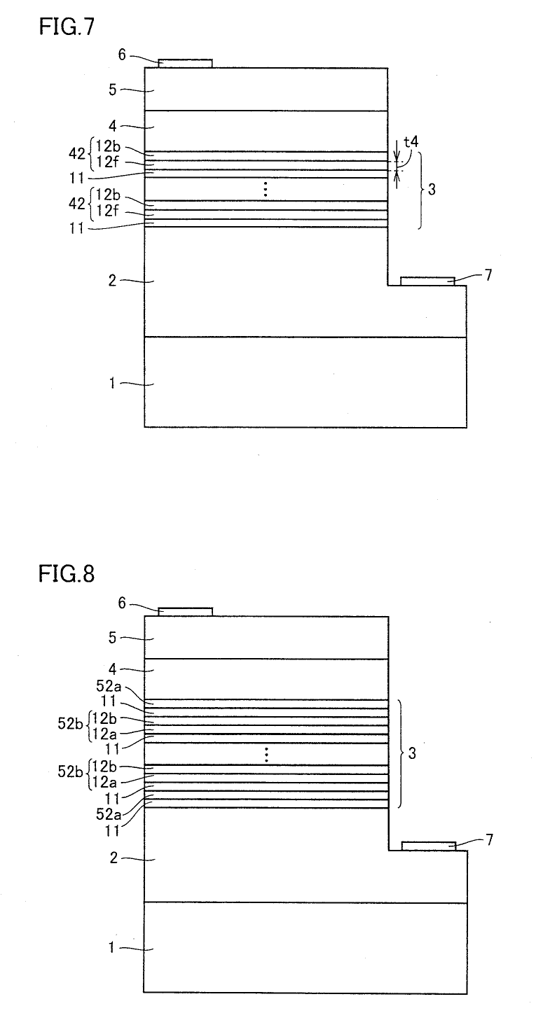

FIG. 7 is a schematic sectional view of a nitride semiconductor light-emitting diode device according to a third embodiment of the present invention. The feature of the nitride semiconductor light-emitting diode device according to the third embodiment resides in that barrier layers 42 having two-layer structures of AlGaN layers 12f containing at least either Mg or In and GaN layers 12b are employed as the barrier layers of an active layer 3 having a multiple quantum well structure.

In other words, active layer 3 of the nitride semiconductor light-emitting diode device according to the third embodiment has a multiple quantum well structure obtained by repeatedly stacking quantum well layers 11, AlGaN layers 12f and GaN layers 12b in this order from a side closer to an n-type nitride semiconductor layer 2. Lowermost quantum well layer 11 of active layer 3 is in contact with n-type semiconductor layer 2, while GaN layer 12b of uppermost barrier layer 42 of active layer 3 is in contact with a p-type nitride semiconductor layer 4. AlGaN layers 12f of barrier layers 42 are in contact with surfaces of quantum well layers 11, provided on barrier layers 42, closer to p-type nitride semiconductor layer 4.

When quantum well layers 11 are formed by nitride semiconductor crystals containing In, AlGaN layers 12f must be grown at a low temperature (700° C. to 800° C., for example), in order to suppress evaporation of In from quantum well layers 11. While it is difficult to obtain planar growth surfaces when the nitride semiconductor crystals are grown at such a low temperature, planar growth surfaces tend to be obtainable as to AlGaN layers 12f containing at least either Mg or In, also when the nitride semiconductor crystals are grown at such a low temperature (700° C. to 800° C., for example). This is because secondary growth of AlGaN layers 12f is prompted when at least either Mg or In is introduced into AlGaN layers 12f during growth thereof.

Also in active layer 3 of the nitride semiconductor light-emitting diode device according to the third embodiment, barrier layers 42 having the two-layer structures of AlGaN layers 12f and GaN layers 12b are employed similarly to the first embodiment, whereby a diffusion length of holes with respect to electrons in active layer 3 can be increased.

Also in the nitride semiconductor light-emitting diode device according to the third embodiment, therefore, not only the electrons can be inhibited from overflowing into p-type nitride semiconductor layer 4, but also localization of carriers on a side of active layer 3 closer to p-type nitride semiconductor layer 4 can be suppressed by uniformly distributing the carriers in the thickness direction of active layer 3 having the multiple quantum well structure, whereby reduction of luminous efficiency resulting from a droop phenomenon can be suppressed.

When AlGaN layers 12f contain Mg, the Mg concentration in AlGaN layers 12f is preferably at least 1×10¹⁸/cm³ and not more than 1×10²⁰/cm³. If the Mg concentration in AlGaN layers 12f is at least 1×10¹⁸/cm³, Mg functions as a surface active agent, to increase such a tendency that AlGaN layers 12f having planar surfaces are obtained also when the same are grown at a low temperature. If the Mg concentration in AlGaN layers 12f exceeds 1×10²⁰/cm³, crystallinity of AlGaN layers 12f is deteriorated. Therefore, the Mg concentration in AlGaN layers 12f is preferably not more than 1×10²⁰/cm³.

When AlGaN layers 12f contain In, on the other hand, the content of In atoms in AlGaN layers 12f is preferably at least 0.01 atomic % and not more than 5 atomic %. If the content of In atoms in AlGaN layers 12f is at least 0.01 atomic %, In functions as a surface active agent, to increase such a tendency that AlGaN layers 12f having planar surfaces are obtained also when the same are grown at a low temperature. If the content of In atoms in AlGaN layers 12f is not more than 5 atomic %, the band gaps of AlGaN layers 12f are not excessively reduced, whereby reduction of luminous efficiency resulting from a droop phenomenon tends to be further suppressible.

Throughout the specification, the expression that “the content of In atoms in AlGaN layers is at least 0.01 atomic % and not more than 5 atomic %” means that the ratio of the number of atoms of In is at least 0.01 and not more than 5 assuming that the total number of atoms of Al, Ga and In in the AlGaN layers is 100.

The thickness t4 of each AlGaN layer 12f in contact with the surface of corresponding quantum well layer 11 closer to p-type nitride semiconductor layer 4 is preferably at least 1 nm and not more than 4 nm. In this case, uniformity in distribution of carriers into active layer 3 can be improved, whereby reduction of luminous efficiency resulting from a droop phenomenon tends to be further suppressible.

A nitride semiconductor crystal expressed as Alₓ₉Ga_{y9}N (0<x9<1, 0<y9<1 and x9+y9<0) or the like, for example, can be employed as the material for AlGaN layers 12f.

The remaining structure of the third embodiment is similar to that of the first embodiment, and hence redundant description is not repeated.

### Fourth Embodiment

FIG. 8 is a schematic sectional view of a nitride semiconductor light-emitting diode device according to a fourth embodiment of the present invention. The feature of the nitride semiconductor light-emitting diode device according to the fourth embodiment resides in that the structure of an active layer 3 is different from those in the first to third embodiments.

In other words, active layer 3 of the nitride semiconductor light-emitting diode device according to the fourth embodiment has a multiple quantum well structure obtained by repeatedly stacking quantum well layers 11, first barrier layers 52a, quantum well layers 11 and second barrier layers 52b in this order from a side closer to an n-type nitride semiconductor layer 2 so that the stacking is completed on uppermost first barrier layer 52a. First barrier layers 52a are formed by single GaN layers, while second barrier layers 52b have two-layer structures of AlGaN layers 12a and GaN layers 12b provided on AlGaN layers 12a. Lowermost quantum well layer 11 of active layer 3 is in contact with n-type nitride semiconductor layer 2, while uppermost first barrier layer 52a of active layer 3 is in contact with a p-type nitride semiconductor layer 4.

In the nitride semiconductor light-emitting diode device according to the fourth embodiment, corresponding first barrier layer 52a is provided on a side, closer to p-type nitride semiconductor layer 4, of quantum well layer 11 arranged on a position closest to n-type nitride semiconductor layer 2 among quantum well layers 11 constituting active layer 3. In the nitride semiconductor light-emitting diode device according to the fourth embodiment, further, another corresponding first barrier layer 52a is provided on a side, closer to p-type nitride semiconductor layer 4, of quantum well layer 11 arranged on a position closest to p-type nitride semiconductor layer 4 among quantum well layers 11 constituting active layer 3. Remaining quantum well layers 11 other than quantum well layers 11 arranged on the positions closest to n-type and p-type nitride semiconductor layers 2 and 4 respectively are formed in contact with second barrier layers 52b.

In the nitride semiconductor light-emitting diode device according to the fourth embodiment, therefore, second barrier layers 52b having the two-layer structures of AlGaN layers 12a and GaN layers 12b are provided not on end portions of active layer 3 on the sides closer to n- and p-type nitride semiconductor layers 2 and 4 respectively in the thickness direction, but in active layer 3. Therefore, electrons and holes can be gathered on a central portion of active layer 3 in the thickness direction by attaining the aforementioned effect of reducing difference in diffusion length between the electrons and holes in active layer 3.

Also in the nitride semiconductor light-emitting diode device according to the fourth embodiment, therefore, not only the electrons can be inhibited from overflowing into p-type nitride semiconductor layer 4, but also localization of carriers on a side of active layer 3 closer to p-type nitride semiconductor layer 4 can be suppressed by uniformly distributing the carriers in the thickness direction of active layer 3 having the multiple quantum well structure, whereby reduction of luminous efficiency resulting from a droop phenomenon can be suppressed.

The GaN layers constituting first barrier layers 52a can be formed by those similar to GaN layers 12b partially constituting second barrier layers 52b.

The remaining structure of the fourth embodiment is similar to that of the first embodiment, and hence redundant description is not repeated.

### Example 1

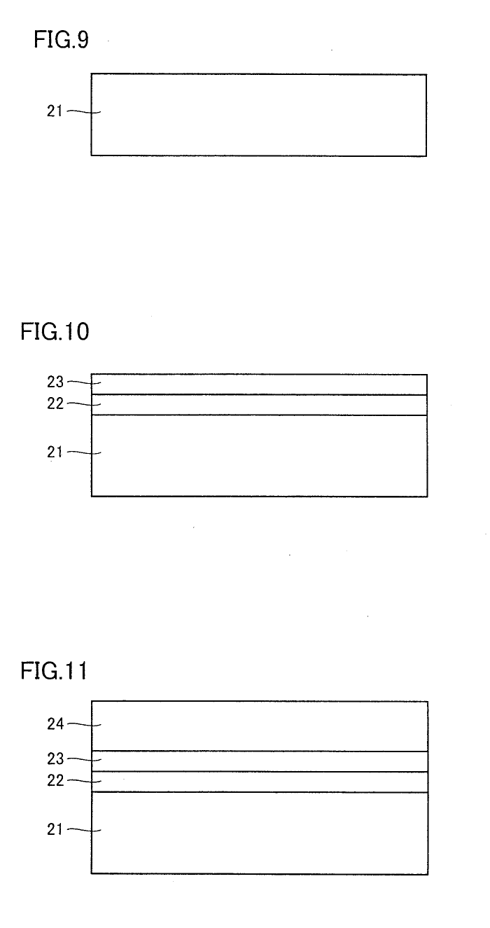

An exemplary method of manufacturing a nitride semiconductor light-emitting diode device according to Example 1 is now described with schematic sectional views of FIGS. 9 to 16. First, a sapphire substrate 21 is prepared and set in an MOCVD apparatus, as shown in FIG. 9. Then, the surface of sapphire substrate 21 is thermally cleaned by heating sapphire substrate 21 set in the MOCVD apparatus to 1000° C. in a hydrogen atmosphere.

Then, a low-temperature GaN buffer layer 22 is grown on the surface of sapphire substrate 21 in a thickness of 20 nm by lowering the temperature of sapphire substrate 21 to 500° C. and supplying TMG (trimethyl gallium) gas and NH₃ (ammonia) gas into the MOCVD apparatus, as shown in FIG. 10.

Then, an undoped GaN layer 23 is grown on the surface of low-temperature GaN buffer layer 22 in a thickness of 2 μm by raising the temperature of sapphire substrate 21 to 1000° C. and supplying TMG gas and NH₃ gas into the MOCVD apparatus, as shown in FIG. 10.

Then, a highly doped n-type GaN layer 24 is grown on the surface of undoped GaN layer 23 in a thickness of 3 μm by supplying TMG gas, NH₃ gas and SiH₄ (silane) gas into the MOCVD apparatus while keeping the temperature of sapphire substrate 21 at 1000° C., as shown in FIG. 11. The SiH₄ gas is so supplied into the MOCVD apparatus that the Si concentration in highly doped n-type GaN layer 24 is 7×10¹⁸/cm³.

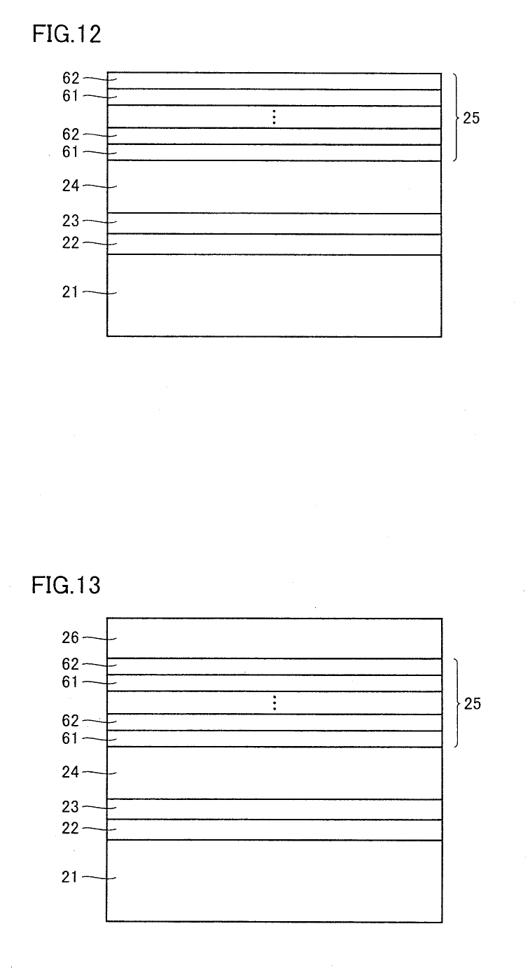

Then, a quantum well layer 61 made of In_{0.2}Ga_{0.8}N is grown on highly doped n-type GaN layer 24 in a thickness of 2.5 nm by lowering the temperature of sapphire substrate 21 to 700° C. and supplying TMG gas, NH₃ gas and TMI (trimethyl indium) gas into the MOCVD apparatus, as shown in FIG. 12. Then, an Al_{0.1}Ga_{0.9}N layer is grown on quantum well layer 61 in a thickness of 2 nm by supplying TMG gas, NH₃ gas and TMA (trimethyl aluminum) gas into the MOCVD apparatus. Thereafter a GaN layer is grown on the Al_{0.1}Ga_{0.9}N layer in a thickness of 6 nm by supplying TMG gas and NH₃ gas into the MOCVD apparatus. Thus, a barrier layer 62 consisting of a laminate of the AlGaN layer and the GaN layer is formed on quantum well layer 61.

Thus, an active layer 25 is formed by alternately repeatedly growing quantum well layers 61 and barrier layers 62 on highly doped n-type GaN layer 24 by six cycles.

Then, a p-type Al_{0.2}Ga_{0.8}N layer is grown on uppermost barrier layer 62 in a thickness of 20 nm by raising the temperature of sapphire substrate 21 to 950° C. and supplying TMA gas, TMG gas, NH₃ gas and CP₂Mg gas (dicyclopentadienyl magnesium) gas into the MOCVD apparatus, and a p-type GaN layer is thereafter grown on the p-type Al_{0.2}Ga_{0.8}N layer in a thickness of 100 nm by supplying TMG gas, NH₃ gas and CP₂Mg gas into the MOCVD apparatus. Thus, a p-type nitride semiconductor layer 26 consisting of a laminate of the p-type Al_{0.2}Ga_{0.8}N layer and the p-type GaN layer is grown on active layer 25, as shown in FIG. 13.

Then, the temperature of sapphire substrate 21 is lowered to room temperature, and sapphire substrate 21 provided with p-type nitride semiconductor layer 26 is thereafter taken out from the MOCVD apparatus and set in a sputtering apparatus.

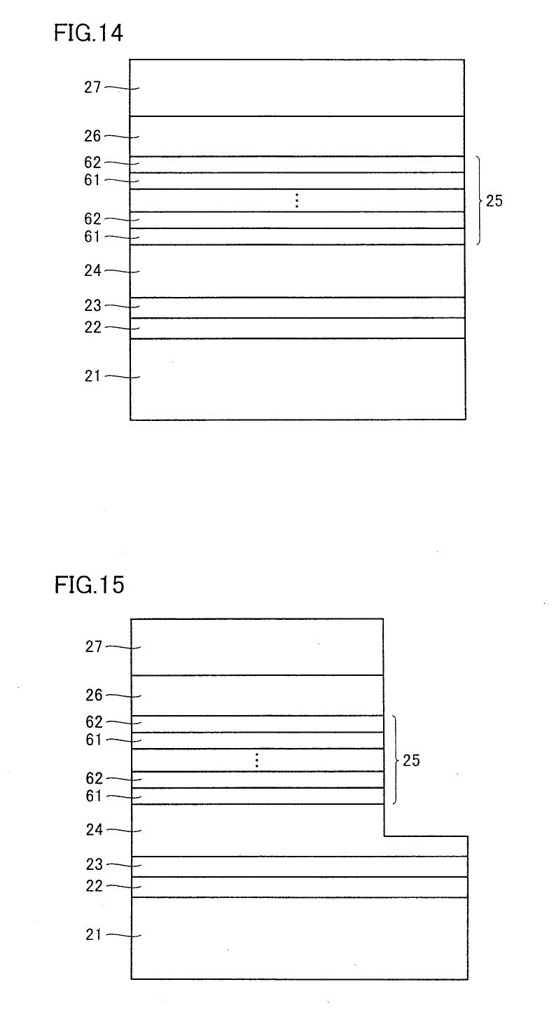

Then, a transparent conductive layer 27 made of ITO is formed on the surface of p-type nitride semiconductor layer 26 in a thickness of 200 nm by sputtering, as shown in FIG. 14.

Then, a mask is formed on part of the surface of transparent conductive layer 27 by photolithography and RIE (Reactive Ion Etching) is thereafter performed, thereby partially removing transparent conductive layer 27, p-type nitride semiconductor layer 26, active layer 25 and highly doped n-type GaN layer 24 and exposing the surface of highly doped n-type GaN layer 24, as shown in FIG. 15.

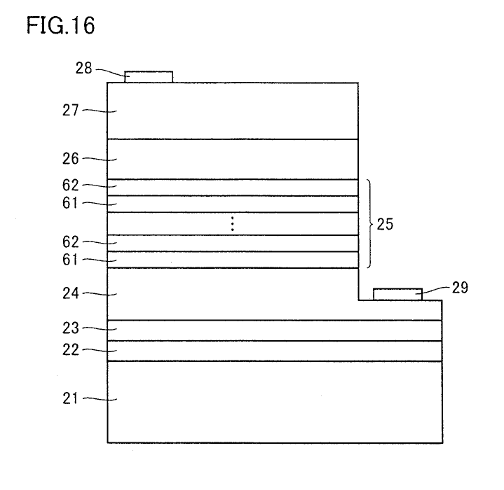

Thereafter Ti layers, Al layers and Au layers are stacked in this order from transparent conductive layer 27 and the exposed surface of highly doped n-type GaN layer 24 respectively thereby forming a p-side pad electrode 28 and an n-side pad electrode 29 on transparent conductive layer 27 and the exposed surface of highly doped n-type GaN layer 24 respectively, as shown in FIG. 16. Thus, the nitride semiconductor light-emitting diode device according to Example 1 is completed.

On the other hand, a nitride semiconductor light-emitting diode device according to comparative example 1 is prepared similarly to the nitride semiconductor light-emitting diode device according to Example 1, except that barrier layers are formed by only GaN layers each having a thickness of 6 nm, without Al_{0.1}Ga_{0.9}N layers each having a thickness of 2 nm.

In the nitride semiconductor light-emitting diode device according to Example 1 prepared in the aforementioned manner, a diffusion length of holes with respect to that of electrons can be relatively enlarged as described above, as compared with the nitride semiconductor light-emitting diode device according to comparative example 1.

In the nitride semiconductor light-emitting diode device according to Example 1, therefore, a peak current position can be shifted to a high-current side, whereby reduction of luminous efficiency can be suppressed when high-density current is injected into the active layer.

### Example 2

A nitride semiconductor light-emitting diode device according to Example 2 is prepared similarly to the nitride semiconductor light-emitting diode device according to Example 1, except that an uppermost barrier layer 62 has a two-layer structure of an Al_{0.1}Ga_{0.9}N layer having a thickness of 2 nm and a GaN layer having a thickness of 4 nm and each of barrier layers 62 other than uppermost barrier layer 62 has a three-layer structure obtained by stacking an Al_{0.1}Ga_{0.9}N layer having a thickness of 2 nm, a GaN layer having a thickness of 4 nm and an In_{0.1}Ga_{0.9}N layer having a thickness of 2 nm from a side closer to a highly doped n-type GaN layer 24.

On the other hand, a nitride semiconductor light-emitting diode device according to comparative example 2 is prepared similarly to the nitride semiconductor light-emitting diode device according to Example 2, except that barrier layers are formed by only GaN layers each having a thickness of 6 nm, without Al_{0.1}Ga_{0.9}N layers each having a thickness of 2 nm and In_{0.1}Ga_{0.9}N layers each having a thickness of 2 nm.

In the nitride semiconductor light-emitting diode device according to Example 2 prepared in the aforementioned manner, a diffusion length of holes with respect to that of electrons can be relatively enlarged as described above, as compared with the nitride semiconductor light-emitting diode device according to comparative example 2.

In the nitride semiconductor light-emitting diode device according to Example 2, therefore, a peak current position can be shifted to a high-current side, whereby reduction of luminous efficiency can be suppressed when high-density current is injected into the active layer.

### Example 3

A nitride semiconductor light-emitting diode device according to Example 3 is prepared similarly to the nitride semiconductor light-emitting diode device according to Example 1, except that Al_{0.1}Ga_{0.9}N layers, each having a thickness of 2 nm, constituting barrier layers 62 are doped with Mg in a concentration of 5×10¹⁸/cm³ by employing CP₂Mg gas.

On the other hand, a nitride semiconductor light-emitting device according to comparative example 3 is prepared similarly to the nitride semiconductor light-emitting diode device according to Example 3, except that barrier layers are formed by only GaN layers each having a thickness of 6 nm, without Al_{0.1}Ga_{0.9}N layers each having a thickness of 2 nm.

In the nitride semiconductor light-emitting diode device according to Example 3 prepared in the aforementioned manner, a diffusion length of holes with respect to that of electrons can be relatively enlarged as described above, as compared with the nitride semiconductor light-emitting diode device according to comparative example 3.

In the nitride semiconductor light-emitting diode device according to Example 3, therefore, a peak current position can be shifted to a high-current side, whereby reduction of luminous efficiency can be suppressed when high-density current is injected into the active layer.

### Example 4

A nitride semiconductor light-emitting diode device according to Example 4 is prepared similarly to the nitride semiconductor light-emitting diode device according to Example 1, except that In is added to Al_{0.1}Ga_{0.9}N layers, each having a thickness of 2 nm, constituting barrier layers 62 and the content of In atoms in the Al_{0.1}Ga_{0.9}N layers is set to 0.5 atomic %.

On the other hand, a nitride semiconductor light-emitting diode device according to comparative example 4 is prepared similarly to the nitride semiconductor light-emitting diode device according to Example 4, except that barrier layers are formed by only GaN layers each having a thickness of 6 nm, without Al_{0.1}Ga_{0.9}N layers each having a thickness of 2 nm.

In the nitride semiconductor light-emitting diode device according to Example 4 prepared in the aforementioned manner, a diffusion length of holes with respect to that of electrons can be relatively enlarged as described above, as compared with the nitride semiconductor light-emitting diode device according to comparative example 4.

In the nitride semiconductor light-emitting diode device according to Example 4, therefore, a peak current position can be shifted to a high-current side, whereby reduction of luminous efficiency can be suppressed when high-density current is injected into the active layer.

The nitride semiconductor light-emitting diode device according to the present invention can be applied to a light-emitting diode device, driven by high current, employed for illumination or the like.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light-emitting diode device comprising:
an n-type nitride semiconductor layer;
a p-type nitride semiconductor layer; and
an active layer provided between said n-type nitride semiconductor layer and said p-type nitride semiconductor layer, wherein
said active layer has a multiple quantum well structure including a quantum well layer and a barrier layer in contact with said p-type semiconductor layer,
said barrier layer consists of a two-layer structure of an AlGaN layer and a GaN layer,
said AlGaN layer included in said barrier layer is in contact with a side of said quantum well layer closer to said p-type nitride semiconductor layer, and
the content of Al atoms in said AlGaN layer is at least 10 atomic %.

2. The nitride semiconductor light-emitting diode device according to claim 1, wherein
the thickness of said AlGaN layer is at least 1 nm and not more than 4 nm.

3. A nitride semiconductor light-emitting diode device comprising:
an n-type nitride semiconductor layer;
a p-type nitride semiconductor layer; and
an active layer provided between said n-type nitride semiconductor layer and said p-type nitride semiconductor layer, wherein
said active layer has a multiple quantum well structure including a quantum well layer, a first barrier layer including an InGaN layer in contact with a side of said quantum well layer closer to said n-type nitride semiconductor layer and a second barrier layer including an AlGaN layer in contact with a side of said quantum well layer closer to said p-type nitride semiconductor layer.

4. The nitride semiconductor light-emitting diode device according to claim 3, wherein
the thickness of said InGaN layer included in said first barrier layer is at least 1 nm and not more than 4 nm.

5. The nitride semiconductor light-emitting diode device according to claim 3, wherein
said quantum well layer contains In, and
the content of In atoms in said InGaN layer included in said first barrier layer is smaller than the content of In atoms in said quantum well layer.

6. The nitride semiconductor light-emitting device according to claim 5, wherein
the content of said In atoms in said InGaN layer included in said first barrier layer is at least 0.3 times and not more than 0.7 times the content of said In atoms in said quantum well layer.

7. The nitride semiconductor light-emitting diode device according to claim 3, wherein
the thickness of said AlGaN layer included in said second barrier layer is at least 1 nm and not more than 4 nm.

8. A nitride semiconductor light-emitting diode device comprising:
an n-type nitride semiconductor layer;
a p-type nitride semiconductor layer; and
an active layer provided between said n-type nitride semiconductor layer and said p-type nitride semiconductor layer, wherein
said active layer has a multiple quantum well structure including a quantum well layer and a barrier layer in contact with said p-type semiconductor layer,
said barrier layer consists of a two-layer structure of an AlGaN layer and a GaN layer,
said AlGaN layer included in said barrier layer is in contact with a side of said quantum well layer closer to said p-type nitride semiconductor layer, and
said AlGaN layer contains at least either Mg or In.

9. The nitride semiconductor light-emitting diode device according to claim 8, wherein
the Mg concentration in said AlGaN layer is at least 1×10¹⁸/cm³ and not more than 1×10²⁰/cm³.

10. The nitride semiconductor light-emitting diode device according to claim 8, wherein
the content of In atoms in said AlGaN layer is at least 0.01 atomic % and not more than 5 atomic %.

11. The nitride semiconductor light-emitting diode device according to claim 8, wherein
the thickness of said AlGaN layer is at least 1 nm and not more than 4 nm.

12. A nitride semiconductor light-emitting diode device comprising:
an n-type nitride semiconductor layer;
a p-type nitride semiconductor layer; and
an active layer provided between said n-type nitride semiconductor layer and said p-type nitride semiconductor layer, wherein
said active layer has a multiple quantum well structure including a quantum well layer, a first barrier layer consisting of a single GaN layer and a second barrier layer consisting of a two-layer structure of an AlGaN layer and a GaN layer,
said quantum well layer includes a first quantum well layer arranged on a position of said quantum well layer closest to said n-type nitride semiconductor layer and a second quantum well layer arranged on a position of said quantum well layer closest to said p-type nitride semiconductor layer, and
said first barrier layer is arranged on a side of said first quantum well layer closer to said p-type nitride semiconductor layer and a side of said second quantum well layer closer to said p-type nitride semiconductor layer respectively, and said quantum well layer other than said first quantum well layer and said second quantum well layer is formed in contact with said second barrier layer.

13. The nitride semiconductor light-emitting diode device according to claim 1, wherein
the number of quantum well periods in said multiple quantum well structure is at least 6 and not more than 20.

14. The nitride semiconductor light-emitting diode device according to claim 1, wherein
said n-type nitride semiconductor layer, said p-type nitride semiconductor layer and said active layer have major surfaces of c-planes respectively.
